(19) United States
(12) Patent Application Publication
(10) Pub. No.: US 2025/0287584 A1
(43) Pub. Date: Sep. 11, 2025

(54) ONE-TIME PROGRAMMABLE MEMORY CELL

(71) Applicant: STMicroelectronics International N.V., Geneva (CH)

(72) Inventor: Stephane DENORME, Crolles (FR)

(73) Assignee: STMicroelectronics International N.V., Geneva (CH)

(21) Appl. No.: 19/072,425

(22) Filed: Mar. 6, 2025

(30) Foreign Application Priority Data
Mar. 11, 2024 (FR) FR2402394

(51) Int. Cl. H10B 20/25

(52) U.S. Cl. CPC H10B 20/25

(57) ABSTRACT

A one-time programmable memory cell includes a programming element, a first transistor connected between a first selection node and an intermediate node, and a second transistor connected between the intermediate node and a first electrode of the programming element. A second electrode of the programming element is coupled to a programming voltage rail. The first transistor has a first width and the second transistor has a second width smaller than the first width.

### PRIORITY CLAIM

This application claims the priority benefit of French Application for Patent No. 2402394, filed on Mar. 11, 2024, the content of which is hereby incorporated by reference in its entirety to the maximum extent allowable by law.

### TECHNICAL FIELD

The present disclosure generally concerns electronic circuits and, in particular, one-time programmable memory cells and methods of manufacturing such cells.

### BACKGROUND

In a one-time programmable (OTP) memory, each cell is irreversibly programmable. After a single programming, each one-time programmable cell is no longer programmable, and is accessible in read-only mode. After the programming of all memory cells, the memory then becomes a read-only memory.

One-time programmable memories are, for example, used to perform data storage or in trimming circuits. Such memories may comprise a large number of memory cells. There thus exists a need for one-time programmable memory cells with a small bulk.

### SUMMARY

An embodiment provides a one-time programmable memory cell comprising: a first transistor connected between a first selection node and an intermediate node; and a second transistor connected between the intermediate node and a first electrode of a programming element, wherein a second electrode of the programming element is coupled to a programming voltage rail, the first transistor having a first width and the second transistor having a second width smaller than the first width.

According to an embodiment, the programming voltage rail is configured to receive a voltage greater than a voltage applied to the gate of the second transistor.

According to an embodiment, the programming element is a third transistor having its gate coupled to the programming voltage rail, the gate of the third transistor forming the second electrode of the programming element.

According to an embodiment, the second width is equal to a third width, the third width corresponding to the width of the third transistor.

According to an embodiment, the first electrode of the programming element is formed by one of the source or the drain of the third transistor.

According to an embodiment, the programming element is a capacitor.

According to an embodiment, the transistors are MOS-type transistors.

According to an embodiment, the first width corresponds to the gate width of the first transistor and the second width corresponds to the gate width of the second transistor.

According to an embodiment, the sum of the second width and of the third width is smaller than the first width.

Another embodiment provides a memory array comprising: a first memory cell such as described hereabove; and a second memory cell such as described hereabove; the second electrode of the programming element of the first and second cells being formed by a single continuous conductor.

According to an embodiment, the first and second memory cells are interleaved with respect to each other and the sum of the second width and of the third width is smaller than the difference between the first width and the width of an insulating trench separating the first and second memory cells.

Another embodiment provides an electronic device comprising a memory comprising one-time programmable cells, the memory comprising the memory array described hereabove.

Another embodiment provides a method of manufacturing a one-time programmable memory cell, comprising: the forming of a first transistor connected between a first selection node and an intermediate node, with a first width; the forming of a second transistor, with a second width smaller than the first width, connected between the intermediate node and a first electrode of a programming element; and the forming of the programming element, a second electrode of the programming element being coupled to a programming voltage rail.

Another embodiment provides a method of manufacturing a memory array comprising: the manufacturing of a first memory cell according to the method described hereabove; and the manufacturing a second memory cell according to the method described hereabove; the second electrode of the programming element of the first and second cells being formed by a single continuous conductor.

According to an embodiment, the first and second memory cells are interleaved with respect to each other and the sum of the second width and of the third width is smaller than the difference between the first width and the width of an insulating trench separating the first and second memory cells.

### BRIEF DESCRIPTION OF THE DRAWINGS

The foregoing features and advantages, as well as others, will be described in detail in the rest of the disclosure of specific embodiments given as an illustration and not limitation with reference to the accompanying drawings, in which:

FIG. 1 schematically shows an example of a one-time programmable memory comprising a plurality of memory cells;

FIG. 2 shows a circuit of a one-time programmable memory cell of FIG. 1;

FIG. 3 is a cross-section view of a one-time programmable memory cell;

FIG. 4 is a top view of a memory comprising six one-time programmable memory cells;

FIG. 5 is a top view of two one-time programmable memory cells of FIG. 3; and

FIG. 6 schematically shows an example of a device comprising the one-time programmable memory cell of FIG. 2 or 3.

### DETAILED DESCRIPTION

Like features have been designated by like references in the various figures. In particular, the structural and/or functional features that are common among the various embodiments may have the same references and may dispose identical structural, dimensional and material properties.

For clarity, only those steps and elements which are useful to the understanding of the described embodiments have been shown and are described in detail. In particular, the operation of and the methods of manufacturing a transistor are known by those skilled in the art and will not be detailed.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, where reference is made to absolute position qualifiers, such as “front”, “back”, “top”, “bottom”, “left”, “right”, etc., or relative position qualifiers, such as “top”, “bottom”, “upper”, “lower”, etc., or orientation qualifiers, such as “horizontal”, “vertical”, etc., reference is made unless otherwise specified to the orientation of the drawings.

Unless specified otherwise, the expressions “about”, “approximately”, “substantially”, and “in the order of” signify plus or minus 10%, preferably of plus or minus 5%.

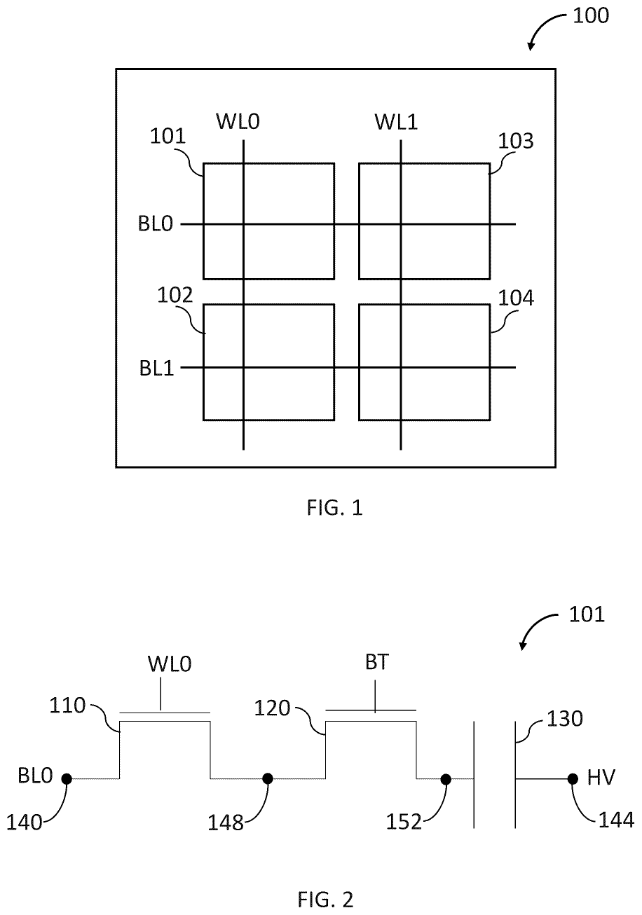

FIG. 1 schematically shows an example of a one-time programmable memory 100 comprising four memory cells 101 to 104.

Although in the example of FIG. 1, memory 100 comprises four memory cells 101 to 104, it will be obvious to those skilled in the art that a smaller or larger number of memory cells may be present in memory 100.

The four memory cells are arranged in rows and in columns, so that the memory cells of a same row are coupled to a same row conductor configured to be powered with selection voltages BL0, BL1, and that the memory cells of a same column are coupled to a same column conductor configured to be powered with selection voltages WL0, WL1. Each of the memory cells is thus coupled to one of selection voltages BL0, BL1 and to one of selection voltages WL0, WL1.

Each of memory cells 101 to 104 comprises a programming element, not shown in FIG. 1. The programming element may, for example, be in one of two states: a first blank state, before programming, and a second state, after programming, which enables to store one bit of binary data. The electrical conductivity of the programming element, for example, is irreversibly modified during the programming. For example, the conductivity of the programming element is higher in the second state than in the first state. The measurement of the electrical conductivity of one of memory cells 101 to 104 enables to determine the state of the programming element.

During a step of programming or of reading from one of memory cells 101 to 104, a memory cell is selected via selection voltage BL0, BL1 and selection voltage WL0, WL1.

Each of selection voltages WL0, WL1, BL0, BL1 may, for example, take one of two voltage values: a low voltage level and a high voltage level. The application of the low voltage level for selection voltage BL0 activates, for example, all the memory cells in the corresponding cell row, memory cells 101 and 103 in the example of FIG. 1, and the application of the high voltage level for selection voltage WL0 activates, for example, all the memory cells in the corresponding cell column, memory cells 101 and 102 in the example of FIG. 1. Only the memory cell then simultaneously receiving the low voltage level in selection voltage BL0 and the high voltage level in selection voltage WL0 is configured so that its programming element transits from the first state to the second state during a programming step and so that its electrical conductivity can be measured during a readout step. Such a memory 100 can be programmed and read from, one memory cell at a time. According to an embodiment, a plurality of memory cells of a same row or of a same column can be programmed simultaneously, by applying, for example, a selection voltage WL0 and a plurality of selection voltages BL0, BL1 or conversely.

FIG. 2 shows a circuit of a one-time programmable memory cell 101 of FIG. 1. A similar circuit configuration applies for the cells 102, 103, 104.

Memory cell 101 comprises, for example, a transistor 110, a transistor 120, and programming element 130, series-connected between a selection node 140 and a power supply node 144.

Selection node 140 is configured, for example, to receive selection voltage BL0. Power supply node 144 is, for example, coupled to a voltage rail configured to be powered with a voltage HV.

Transistor 110 is connected between selection node 140 and an intermediate node 148. The gate of transistor 110 is configured to be powered with selection voltage WL0.

Transistor 120 is connected between intermediate node 148 and another intermediate node 152. The gate of transistor 120 is, for example, coupled to a voltage rail configured to be powered with a voltage BT. Transistors 110 and 120 are, for example, p-channel or n-channel MOS (Metal Oxide Semiconductor) transistors. According to an embodiment, transistors 110 and 120 are transistors of MOS silicon-on insulator (SOI) type.

Programming element 130 has a first electrode connected to node 152 and a second electrode connected to node 144. In the example of FIG. 2, programming element 130 is a capacitor. According to other embodiments, not shown in FIG. 2, programming element 130 is a transistor. Programming element 130 comprises, for example, a layer of an insulating material positioned between two conductive layers. The application of a high voltage, sometimes called a breakdown voltage, between the two conductive layers irreversibly changes the conductivity of the insulating layer. Programming element 130 is thus in the first state before the application of this high voltage and in the second state afterwards. This enables to program memory cell 101. The reading from memory cell 101 is performed by measuring the conductivity of the programming element, which is for example higher in the second state.

Voltage HV is for example in the range from 3 V to 5 V during the programming, for example from 4 V to 5 V.

The low voltage level of selection voltages BL0 and WL0 is, for example, 0 V. The high voltage level, for selection voltages BL0 and WL0, is for example in the range from 0.5 V and 1.5 V, for example from 0.9 V to 1.1 V.

Voltage BT is, for example, higher than the high voltage level of voltage WL0 and lower than voltage HV, for example in the range from 2 V to 2.5 V. According to an embodiment, during a readout step, voltages HV and BT are decreased to avoid an unintentional programming of a programming element and to decrease the power consumption of memory 100, while remaining sufficient to ensure the reading of the state of programming element 130.

The width of transistor 120 is smaller than the width of transistor 110, which enables to decrease the cell size without having this decrease the programming current during a write operation. Indeed, in the case where transistors 110 and 120 have the same width, since voltage BT is higher than the high voltage level of voltage WL0, transistor 110 limits the maximum current that can flow through memory cell 101, between node 140 and node 144. Thus, the width of transistor 120 may be decreased to a certain extent without impacting the value of the maximum current. For example, the width of transistor 120 is selected so that this transistor has a resistance RON, when voltage BT is applied to its gate, smaller than or equal to the resistance RON of transistor 110, when the high voltage level of voltage WL0 is applied to its gate.

During a programming step, selection voltage BL0 takes the value of the low voltage level and selection voltage WL0 takes the value of the high voltage level. The voltage levels are configured so that transistor 110 is then conductive and that a current flows between selection node 140 and node 148. Voltage BT is selected so that, when transistor 110 is conductive, transistor 120 is also conductive and the current flows between node 148 and the first electrode of programming element 130. Voltage HV, applied to the second electrode of programming element 130, is selected to be sufficiently high for the breakdown voltage to be reached between the first and the second electrode and for programming element 130 to transit from the first state to the second state.

During a readout step, selection voltage BL0 takes the value of the low voltage level and selection voltage WL0 takes the value of the high voltage level so that a current flows between selection node 140 and node 144, as described hereabove for a write step. However, voltages BL0, WL0, BT, and HV are then configured so that the voltage between the two electrodes of programming element 130 is lower than the breakdown voltage to ensure that memory cell 101 is only read from and not programmed.

Voltages HV, BT, WL0, and BL0 are also selected so that the breakdown voltage is not reached when selection voltage BL0 is at the high voltage level or selection voltage WL0 is at the low voltage level.

Although two access transistors 110, 120 are shown in FIG. 2, a larger number of access transistors, for example three, may be series-connected with programming element 130. For example, among the access transistors, one of the transistors is transistor 110, and the others are transistors similar to transistor 120, and receive at their gates fixed voltages which are, for example, increasing the closer it is to programming element 130.

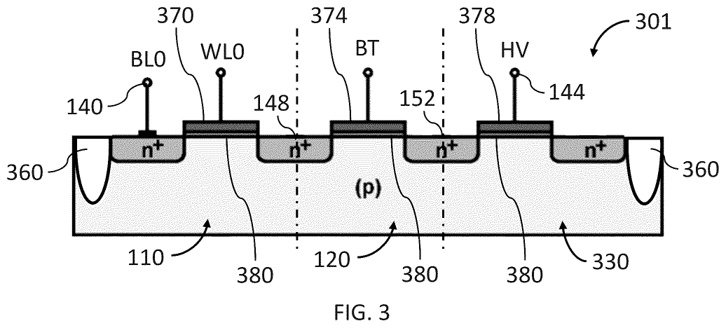

FIG. 3 is a cross-section view of a one-time programmable memory cell 301.

Certain elements of FIG. 3 are similar to those of FIG. 2 and have been referenced with the same reference numerals and will not be described again in detail.

In the example of FIG. 3, transistor 110 and transistor 120 are n-channel MOS transistors. The programming element 130 of memory cell 301 is an n-channel MOS transistor 330. The first electrode of the programming element corresponds to a connection node of transistor 330, for example its source, and the second electrode of the programming element corresponds to the gate of transistor 330. The third connection node of transistor 330, for example, its drain, is for example not powered with voltage, and is thus floating. According to another embodiment, the drain and the source of transistor 330 are connected to each other. When a sufficiently high voltage is applied between node 152, for example the source of transistor 330, and node 144 corresponding to the gate of transistor 330, the oxide layer located between the gate and the substrate of the third transistor 330 is irreversibly modified and its electrical conductivity is increased.

In the example of FIG. 3, the substrate of transistors 110, 120, 330 is p-doped (as indicated by “(p)”) and the drain and the source of transistors 110, 120, 330 are heavily n-doped (as indicated by “(n+)”). Two neighboring transistors share a connection node, for example the drain of transistor 110 is one with the source of transistor 120 and the drain of transistor 120 is one with the source of transistor 330. The transistors are, for example, surrounded by shallow trench insulation (STI) trenches 360, enabling to insulate memory cell 301 from its immediate environment, for example, from another memory cell 301.

According to embodiments, transistors 110, 120, 130 are transistors of fully depleted SOI (FDSOI, for Fully Depleted Silicon On Insulator) MOS type. In such SOI structures, an insulating layer is, for example, present between the doped silicon regions of the transistors and the substrate.

The gate of each transistor 110, 120, 330 is, for example, formed by a gate stack comprising a gate conductor 370, 374, and 378 respectively, separated from the silicon substrate by a layer of insulator 380, for example of oxide.

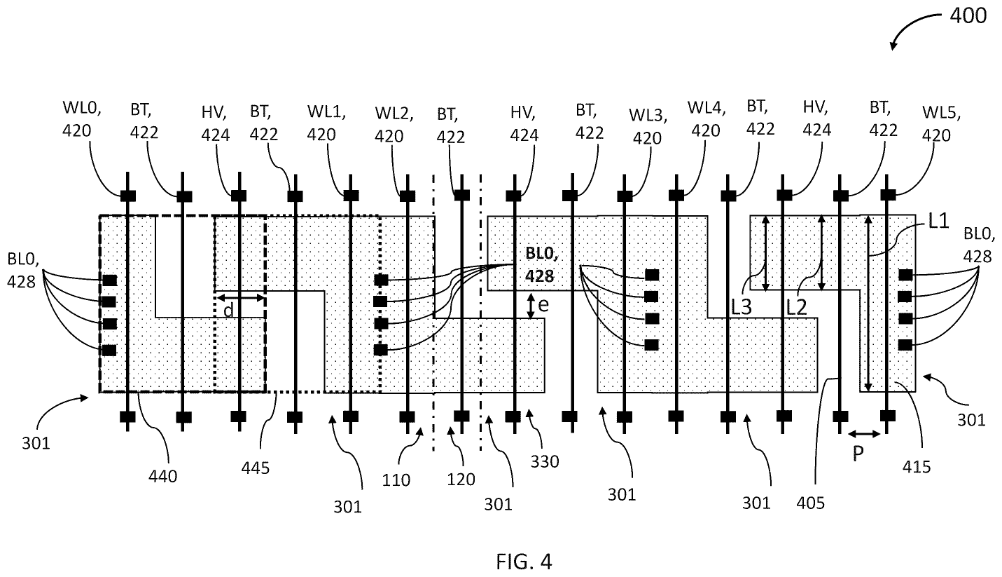

FIG. 4 is a top view of a memory 400 comprising six memory cells, each implemented, for example, by the one-time programmable memory cell 301 of FIG. 3.

Certain elements of FIG. 4 are similar to those of FIG. 2 or 3 and have been referenced with the same reference numerals and will not be described again in detail.

FIG. 4 illustrates certain layers of the architecture of a one-time programmable memory 400 comprising a row formed of six memory cells 301. There are shown polysilicon conductive tracks 405, for example, gate conductors for transistors or an electrode of a capacitor, metal contacts 420, 422, 424, 428 configured to receive a voltage, and doped silicon layers 415, for example the substrate of the transistors.

Although this is not visible in the view of FIG. 4, each transistor 110, 120, 330 comprises the gate stack illustrated in FIG. 3 extending over the doped silicon region 415 covered by conductive track 405. The gate conductor 370, 374, 378 of each transistor 110, 120, 330 is, for example, formed by the portion of conductive track 405 above doped region 415, and the extension of this conductive track 405 is used to form the connection between the gate conductors and metal contacts 420, 422, 424.

In the example of FIG. 4, the gate of transistor 120 has a width L2 smaller than a width L1 of the gate of transistor 110. In the example of FIG. 4, the width L2 of the gate of transistor 120 is equal to a width L3 of the gate of transistor 330. In other embodiments, the width L2 of the gate of transistor 120 is in the range from L3 to L1.

Each of the six memory cells 301 is configured to receive the same selection voltage BL0, applied, via metal contacts 428, to its selection node 140, not shown in FIG. 4, coupled to the source of its transistor 110. Each of the six memory cells 301 is configured to receive one of selection voltages WL0, WL1, WL2, WL3, WL4, WL5, via metal contacts 420 connected to its gate conductor 370. Each of the six memory cells 301 is configured to receive voltage BT, via the metal contacts 422 coupled to its gate conductor 374. Each of the six memory cells 301 is configured to receive voltage HV, via the metal contacts 424 coupled to its gate conductor 378.

The doped silicon regions 415 are, for example, surrounded by shallow insulation trenches, for example to be insulated from other neighboring memory cells 301.

The doped silicon regions 415 of each memory cell 301 does not have the shape of a rectangle, since the width L1 of the gate of transistor 110 is greater than widths L2 and L3. In the example of FIG. 4, widths L2 and L3 being equal, each memory cell 301 has the shape of an “L”.

A first and a second neighboring memory cell 301 are, for example, rotated by 180° in the plane with respect to each other, so that the first one of the two cells has the shape of an “L” and the second one has the shape of an inverted “L”. In addition, the two neighboring memory cells 301 are, for example, nested. To illustrate this feature, there are drawn in FIG. 4 a first rectangle 440 of width L1 and having the length of the first memory cell 301, surrounding the first memory cell 301, and a second rectangle 445 of width L1 and having the length of the second memory cell 301, surrounding the second memory cell 301. The first and second rectangles partially overlap over a length d. Accordingly, the length of a pattern formed of two adjacent memory cells 301, arranged as described above, is smaller than twice the length of a memory cell 301, while respecting minimum spacings, determined by manufacturing methods implemented during the manufacturing of memory 400, between neighboring doped silicon regions 415 and between conductive tracks 405.

In the case where widths L2 and L3 are equal, this arrangement of nested cells is possible when L2 and L3 are smaller than L1 divided by 2 and preferably smaller than (L1-e)/2, where e is the width of the insulating trench separating two doped silicon regions 415 of neighboring memory cells 301. For example, width e is equal to or greater than a minimum spacing between two doped silicon regions 415, in the transistor width direction, the minimum spacing being for example determined by manufacturing methods implemented during the manufacturing of memory 400.

A first pattern and a second pattern are, for example, juxtaposed so that the source of the transistor 110 of the second memory cell 301 of the first pattern is one with the source of transistor 110 of the first memory cell 301 of the second pattern. These sources are, for example, coupled to the same metal contacts 428.

The arrangement of the memory cells 301 and the difference between the width L1 of the gate of transistor 110 and the width L2 of the gate of transistor 120 enable, for example, to use a same metal contact 424 and a same conductive track 405 to form the second electrodes of the programming elements 130 of two neighboring memory cells 301. In the example of FIG. 4, the metal contacts 424 and the gate conductors 378 of the transistors 330 of two neighboring memory cells 301 are shared. Accordingly, only 5 conductive tracks 405, instead of 6, are used to power two memory cells 301.

The minimum distance separating two conductive tracks 405 (“P”, for pitch) is, for example, imposed for manufacturing methods and constrains the minimum width that memory 400 can have. By using one less conductive track 405 per pattern, memory 400 has a width decreased by at least P/2 per memory cell 301 present on a row.

According to embodiments in which a greater number of access transistors are series-connected with programming element 130, the width of a memory cell 301 remains decreased by at least P/2. For example, the width of a memory cell 301 comprising two access transistors 110, 120 is 5P/2 because 5 conductive tracks are used for two memory cells 301. For example, the width of a memory cell comprising three access transistors, not shown in FIG. 4, is 7P/2 and one conductive track is used by two neighboring memory cells.

Although memory 400 comprising memory cells 301 comprising three transistors has been detailed, memory cells 101 comprising a capacitor or another programming element 130 in place of transistor 330 is also possible so that each memory cell 101 comprises two transistors.

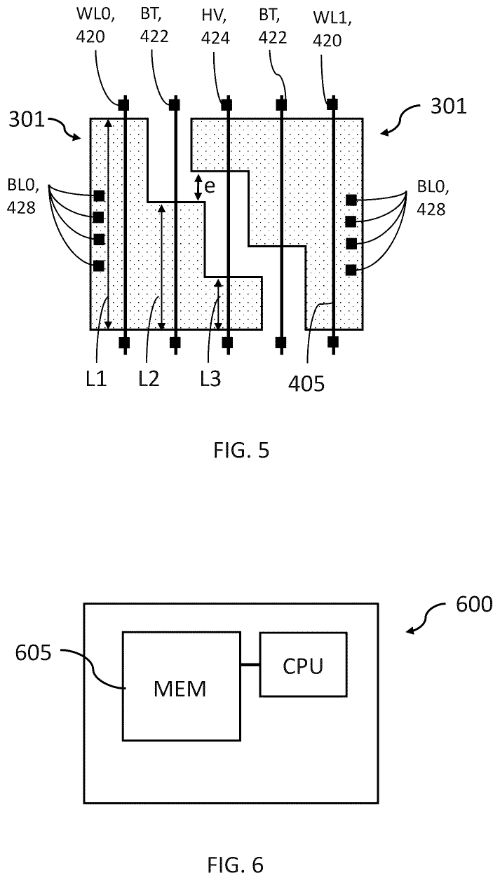

FIG. 5 is a top view of a pattern comprising two one-time programmable memory cells 301 of FIG. 3.

Certain elements of FIG. 5 are similar to those of FIG. 4 and have been referenced with the same reference numerals and will not be described again in detail.

FIG. 5 illustrates an example of arrangement of two memory cells 301 in which the width L2 of the gate of transistor 120 is in the range from L3 to L1.

Widths L2 and L3 being no longer equal in the example of FIG. 5, memory cells 301 no longer have the shape of an “L”. The staggered arrangement described for FIG. 4 with two nested memory cells 301 remains possible and is copied in FIG. 5. As in the example of FIG. 4, a same conductive line 405 is used to form the gate conductors 378 of the transistor 330 of each of the two memory cells 301.

In the case of FIG. 5, it is possible to nest the cells when L2+L3 is lower than L1, and preferably when L2+L3 is lower than L1-e.

The surface area of memory cells 301 remains decreased by decreasing the width L2 of the gate of transistor 120, and only 5 conductive tracks 405 are for example used to power two memory cells 301.

FIG. 6 schematically shows an example of a device 600 comprising the memory cell 101 of FIG. 2 or the memory cell 301 of FIG. 3.

Device 600 is an electronic device comprising a memory 605 (MEM), for example the memory 400 of FIG. 4. Memory 605 comprises an array formed by a plurality of memory cells 101 or 301 arranged in rows and in columns, as well as circuits, not shown in FIG. 6, configured to program and to read from the memory cells. Device 600 for example also comprises a data processing circuit, such as a CPU (Central Processing Unit) coupled to memory 605.

Device 600 is, for example, a laptop computer, a cell phone, an electronic tablet, or a similar device.

An advantage of providing a one-time programmable memory cell according to the embodiments described in the present disclosure, in which the width L2 of the gate of transistor 120 is smaller than the width L1 of transistor 110, is to decrease the surface area of the memory cell and to decrease the surface area of memory 400 comprising these memory cells. An advantage of using a single conductive track 405 to power the programming elements 130 of two separate memory cells, in addition to the gain in surface area, is a gain in security by making the detection of a data item stored in memory 400 more difficult. For example, the position of two neighboring programming elements 130 is closer and it will be more difficult for a criminal to distinguish their states by techniques of observation of the device containing the memory cells.

Various embodiments and variants have been described. Those skilled in the art will understand that certain features of these various embodiments and variants may be combined, and other variants will occur to those skilled in the art. In particular, the number of memory cells and the number of rows and of columns comprised by memory 400 may be different with respect to the examples shown in the drawings.

Finally, the practical implementation of the described embodiments and variants is within the abilities of those skilled in the art based on the functional indications given hereabove. In particular, the methods of manufacturing transistors and capacitors are within the abilities of those skilled in the art and have not been detailed.

1. A one-time programmable memory cell, comprising:
a programming element;
a first transistor connected between a first selection node and an intermediate node; and
a second transistor connected between the intermediate node and a first electrode of the programming element;
wherein a second electrode of the programming element is coupled to a programming voltage rail; and
wherein the first transistor has a first width, the second transistor has a second width smaller than the first width, and the programming element has a third width; and
wherein a sum of the second width and the third width is less than the first width.

2. The memory cell according to claim 1, wherein the programming voltage rail is configured to receive a voltage greater than a voltage applied to a gate of the second transistor.

3. The memory cell according to claim 1, wherein the programming element comprises a third transistor having a gate forming the second electrode of the programming element which is coupled to the programming voltage rail.

4. The memory cell according to claim 3, wherein the third transistor has the third width, and wherein the second width is equal to the third width.

5. The memory cell according to claim 3, wherein the third transistor has the third width, and wherein the second width is larger than the third width.

6. The memory cell according to claim 3, wherein the first electrode of the programming element is formed by at least one of a source or a drain of the third transistor.

7. The memory cell according to claim 3, wherein a sum of the second width and a third width of the third transistor is smaller than the first width.

8. The memory cell according to claim 1, wherein the programming element is a capacitor.

9. The memory cell according to claim 1, wherein the first and second transistors are MOS-type transistors.

10. The memory cell according to claim 1, wherein the first width corresponds to a gate width of the first transistor and the second width corresponds to a gate width of the second transistor.

11. A memory array, comprising:
a plurality of memory cells including a first memory cell and a second memory cell;
wherein each memory cell of the plurality of memory cells comprises:
a programming element;
a first transistor connected between a first selection node and an intermediate node; and
a second transistor connected between the intermediate node and a first electrode of the programming element;
wherein a second electrode of the programming element is coupled to a programming voltage rail; and
wherein the first transistor has a first width and the second transistor has a second width smaller than the first width; and
wherein the second electrode of the programming element of the first and second memory cells is formed by a single continuous conductor.

12. The memory array according to claim 11, wherein the programming element of each memory cell has a third width, and wherein a sum of the second width and the third width is less than the first width.

13. The memory array according to claim 11, wherein the programming element of each memory cell comprises a third transistor having a gate forming the second electrode of the programming element which is coupled to the programming voltage rail.

14. The memory array according to claim 13, wherein the third transistor has a third width, and wherein the second width is equal to the third width.

15. The memory array according to claim 13, wherein the third transistor has a third width, and wherein the second width is greater than the third width.

16. The memory array according to claim 13, wherein the first and second memory cells are interleaved with respect to each other and a sum of the second width and the third width is smaller than a difference between the first width and a width of an insulating trench separating the first and second memory cells.

17. An electronic device, comprising: the memory array according to claim 11.

18. A method of manufacturing a one-time programmable memory cell, comprising:
forming a programming element;
forming a first transistor connected between a first selection node and an intermediate node, the first transistor having a first width;
forming a second transistor connected between the intermediate node and a first electrode of the programming element, the second transistor having a second width smaller than the first width; and
wherein a second electrode of the programming element is coupled to a programming voltage rail;
wherein the programming element has a third width; and
wherein a sum of the second width and the third width is less than the first width.

19. A method of manufacturing a memory array, comprising:
manufacturing a plurality of memory cells including a first memory cell and a second memory cell, wherein each memory cell of the plurality of memory cells is manufactured by the method of claim 18; and
connecting the second electrode of the programming element of the first and second memory cells using a single continuous conductor.

20. The method according to claim 18, wherein forming the programming element comprises forming a third transistor having a gate providing the second electrode of the programming element which is coupled to the programming voltage rail.

21. The method according to claim 20, wherein the third transistor has the third width, and wherein the second width is equal to the third width.

22. The method according to claim 20, wherein the third transistor has the third width, and wherein the second width is larger than the third width.

23. The method according to claim 20, wherein the first and second memory cells are interleaved with respect to each other and a sum of the second width and the third width is smaller than a difference between the first width and a width of an insulating trench separating the first and second memory cells.
